(19) United States
(12) Patent Application Publication
(10) Pub. No.: US 2026/0349026 A1
(43) Pub. Date: Nov. 5, 2026

(54) CONTACT-TYPE TEMPERATURE CONTROL TESTING DEVICE, METHOD OF CONTROLLING TEMPERATURE, TEMPERATURE CONTROLLING SYSTEM, AND TESTED DEVICE

(71) Applicant: MPI CORPORATION, Zhubei City (TW)

(72) Inventor: YUEH-YING LEE, Zhubei City (TW)

(21) Appl. No.: 19/557,251

(22) Filed: Mar. 5, 2026

Related U.S. Application Data
(60) Provisional application No. 63/767,007, filed on Mar. 5, 2025.

(51) Int. Cl. G01R 31/28

(52) U.S. Cl. CPC G01R 31/2875; G01R 31/2877

(57) ABSTRACT

A contact-type temperature control testing device, a method of controlling a temperature, a temperature controlling system, and a tested device. The contact-type temperature control testing device directly contacts a device under test (DUT), performs temperature control, and includes a low-temperature assembly providing a predetermined low temperature, a high-temperature assembly disposed adjacent to the low-temperature assembly, and a gap adjusting member. The high-temperature assembly includes a base and a high-temperature source disposed on the base, and provides a predetermined high temperature. A surface of the base directly contacts the DUT. The low-temperature assembly and/or the high-temperature source conducts a predetermined temperature to the DUT. Two ends of the gap adjusting member are connected to the low-temperature assembly and disposed on the high-temperature assembly, respectively. The gap adjusting member adjusts a mechanical coupling condition between the low-temperature and high-temperature assemblies in response to a temperature change of the high-temperature source.

### CROSS-REFERENCE TO RELATED PATENT APPLICATION

This application claims the benefit of priority to the U.S. Provisional Patent Application Ser. No. 63/767,007, filed on Mar. 5, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a temperature controlling system and a method of controlling a temperature thereof in a semiconductor testing apparatus, and more particularly to a contact-type temperature control testing device in which an adapter directly contacts a device under test and a method of controlling a temperature thereof.

### BACKGROUND OF THE DISCLOSURE

According to how an adapter contacts a device under test (DUT), a temperature controlling system in a semiconductor testing apparatus can be categorized into a direct contact-type thermal touch head and an indirect contact-type thermal air head.

FIG. 1 shows a structural view of an existing direct contact-type temperature control testing system 100, which includes a thermal touch head 100a and a control terminal 100b. From top to bottom, the thermal touch head 100a includes a low-temperature assembly 91 (e.g., a heat exchanger or a heat evaporator that acts as a low-temperature source of a system), a high-temperature assembly 92 (e.g., a heater or a cooling chip and its fixing base that act as a high-temperature source of the system), and a device-under-test (DUT) adapter 93 (hereafter referred to as adapter 93). By controlling the system through a combination of the high-temperature source and the low-temperature source, temperature control can be performed on the adapter 93. In order to prevent heat dissipation, the thermal touch head 100a is provided with an outer housing 94 disposed around the thermal touch head 100a. The control terminal 100b includes a cooling module 81 and a temperature controlling module 82.

During a low-temperature test period, an assembly of the thermal touch head 100a is required to have good thermal conductivity for taking large amounts of heat away from the device under test (DUT) and maintaining the device under test at a set low temperature. Hence, the low-temperature assembly 91, the high-temperature assembly 92, and the adapter 93 are assembled and connected in a laminated contact manner. In addition, when contact temperature control is being performed for the device under test, a predetermined downward pressure is further applied, so that the adapter 93 and the device under test have improved thermal conduction.

The problem in the above-mentioned architecture is the close proximity of the low-temperature source and the high-temperature source, and the low-temperature assembly 91, the high-temperature assembly 92, and the adapter 93 are forced into closer contact due to the above-mentioned downward pressure. As such, when a heater of the high-temperature assembly 92 is heating up, heat is downwardly conducted to the adapter 93, and is also simultaneously and upwardly conducted to the low-temperature assembly 91. In other words, while good thermal conductivity is beneficial for low-temperature conduction, a large amount of heat will also flow back to the low-temperature assembly 91 at a high temperature, thereby causing the following problems.

Firstly, a temperature rise of the adapter is slow, and may not be able to reach a set temperature.

Furthermore, a large number of heat sources are conducted to a low-temperature assembly at a head portion. A temperature of an outer housing of the thermal touch head is thus likely to be overly high, or a temperature of a refluxed refrigerant or coolant is thus likely to rise. If the temperature is overly high, a chiller at a control terminal may have an increased load or be subjected to abnormal shutdown.

Therefore, how to enhance a balancing effect between thermal conduction and cooling of the contact-type thermal touch head through improvements in structural design, so as to overcome the above-mentioned problems, has become an important issue to be solved in the related art.

### SUMMARY OF THE DISCLOSURE

In response to the above-referenced technical inadequacies, the present disclosure provides a contact-type temperature control testing device, a method of controlling a temperature, a temperature controlling system, and a tested device.

In order to solve the above-mentioned problems, one of the technical aspects adopted by the present disclosure is to provide a contact-type temperature control testing device, which directly contacts a device under test and performs temperature control. The contact-type temperature control testing device includes a low-temperature assembly, a high-temperature assembly, and a gap adjusting member. The low-temperature assembly is configured to provide a predetermined low temperature. The high-temperature assembly is disposed adjacent to the low-temperature assembly, and includes a high-temperature source and a base. The high-temperature source is disposed on the base, and is configured to provide a predetermined high temperature. A surface of the base is configured to directly contact the device under test, and at least one of the low-temperature assembly or the high-temperature source conducts a predetermined temperature to the device under test. One end of the gap adjusting member is connected to the low-temperature assembly, and another end of the gap adjusting member is disposed on the high-temperature assembly. The gap adjusting member is configured to adjust a mechanical coupling condition between the low-temperature assembly and the high-temperature assembly in response to a temperature change of the high-temperature source. The mechanical coupling condition corresponds to a lower thermal conductivity level when a temperature of the high-temperature source rises, and the mechanical coupling condition corresponds to a higher thermal conductivity level when the temperature of the high-temperature source decreases.

In order to solve the above-mentioned problems, another one of the technical aspects adopted by the present disclosure is to provide a method of controlling a temperature of a device under test in a direct contact manner. The method includes: providing the above-mentioned contact-type temperature control testing device; using a lower surface of the base of the high-temperature assembly to directly contact the device under test; providing, by the high-temperature source, the predetermined high temperature in a heating operation state, and using the gap adjusting member to adjust the mechanical coupling condition between the low-temperature assembly and the high-temperature assembly in response to the temperature change of the high-temperature source, so as to correspond to the lower thermal conductivity level; and providing, by the low-temperature assembly, the predetermined low temperature in a cooling operation state, and using the gap adjusting member to adjust the mechanical coupling condition between the low-temperature assembly and the high-temperature assembly in response to the temperature change of the high-temperature source, so as to correspond to the higher thermal conductivity level.

In order to solve the above-mentioned problems, yet another one of the technical aspects adopted by the present disclosure is to provide a temperature controlling system, which includes the above-mentioned contact-type temperature control testing device, a cooling module connected to the low-temperature assembly, and a temperature controlling module. The temperature controlling module is configured to monitor and adjust a temperature of the low-temperature assembly and a temperature of the high-temperature assembly, so as to maintain an estimated temperature of the surface of the base that contacts the device under test.

In order to solve the above-mentioned problems, still another one of the technical aspects adopted by the present disclosure is to provide a tested device, which is an electronic device under test having a temperature that is controlled by the above-mentioned method.

Therefore, in the contact-type temperature control testing device provided by the present disclosure, the mechanical coupling condition between the low-temperature assembly and the high-temperature assembly is adjusted by the gap adjusting member in response to the temperature change of the high-temperature source. When the temperature of the high-temperature source rises (e.g., during a high-temperature operation), the mechanical coupling condition corresponds to the lower thermal conductivity level, so as to prevent a slow temperature rise in a device-under-test (DUT) adapter, prevent a casing of the contact-type temperature control testing device from having an overly high temperature, and avoid situations that may result in an increased load or abnormal shutdown of a chiller of a temperature control testing system. When the temperature of the high-temperature source decreases (e.g., during a low-temperature operation), the mechanical coupling condition corresponds to the higher thermal conductivity level, so that thermal conduction of the low-temperature assembly can effectively reach the DUT adapter. In this way, a low temperature that is set can be quickly achieved.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a system block diagram of a contact-type temperature control testing device;

FIG. 2 is a schematic front view of the contact-type temperature control testing device according to a first embodiment of the present disclosure;

FIG. 3 is a schematic perspective view of the contact-type temperature control testing device according to the first embodiment of the present disclosure;

FIG. 4 is a schematic cross-sectional view taken along line IV-IV of FIG. 3;

FIG. 5 is a schematic cross-sectional view taken along line V-V of FIG. 3;

FIG. 6 is a schematic cross-sectional view taken along line VI-VI of FIG. 3;

FIG. 7 is a schematic view of the contact-type temperature control testing device without a low-temperature source according to the present disclosure;

FIG. 8 is a schematic cross-sectional view taken along line VIII-VIII of FIG. 3;

FIG. 9 is a schematic perspective view of the contact-type temperature control testing device according to a second embodiment of the present disclosure;

FIG. 10 is a schematic exploded view of the contact-type temperature control testing device according to the second embodiment of the present disclosure;

FIG. 11 is a schematic cross-sectional view taken along line XI-XI of FIG. 9;

FIG. 12 is a schematic cross-sectional view taken along line XII-XII of FIG. 9;

FIG. 13 is a schematic cross-sectional view taken along line XIII-XIII of FIG. 9;

FIG. 14 is a schematic cross-sectional view taken along line XIV-XIV of FIG. 9; and

FIG. 15 is a schematic cross-sectional view taken along line XV-XV of FIG. 9.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

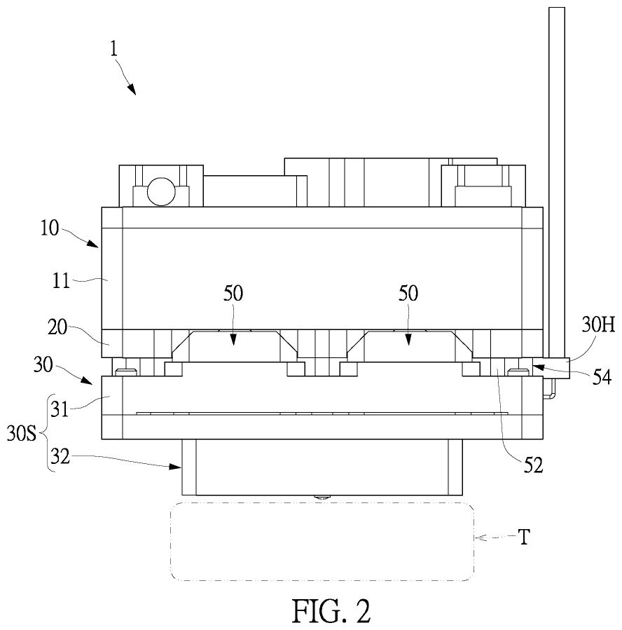

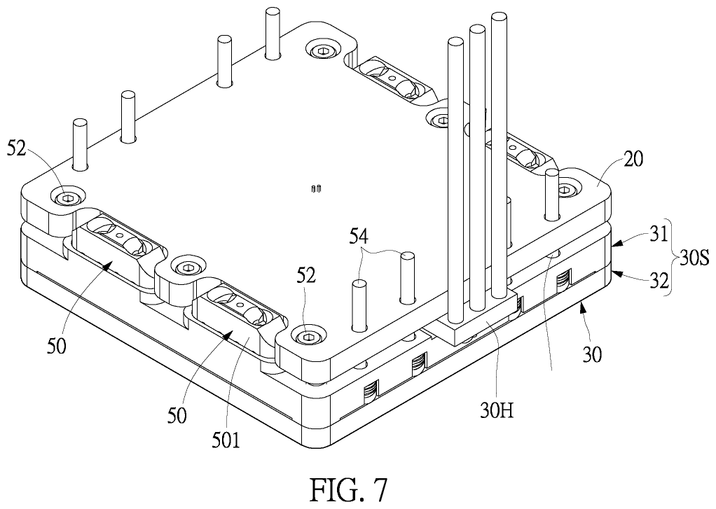

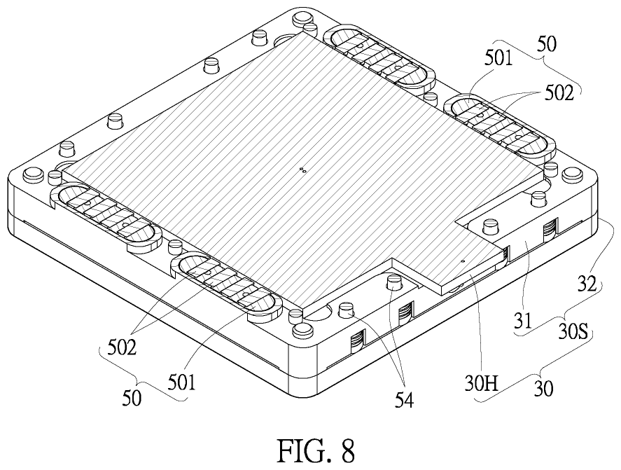

Referring to FIG. 2 to FIG. 8, a first embodiment of the present disclosure provides a contact-type temperature control testing device, which directly contacts a device under test T and performs temperature control. The device under test T can be any electronic device or electronic component that needs to undergo a high-temperature or low-temperature resistance test. A contact-type temperature control testing device 1 includes a low-temperature assembly 10, a high-temperature assembly 30, and a gap adjusting member 50. The low-temperature assembly 10 is configured to provide a predetermined low temperature, or can be referred to as a cooling assembly. The low-temperature assembly 10 can be, for example, a heat exchanger or an evaporative cooler. By using a refrigerant fluid (e.g., water) as a cooling medium, the heat exchanger takes away heat of a fluid. Furthermore, the low-temperature assembly 10 of the present embodiment includes a low-temperature source and a main body 11. The low-temperature source is disposed in the main body 11.

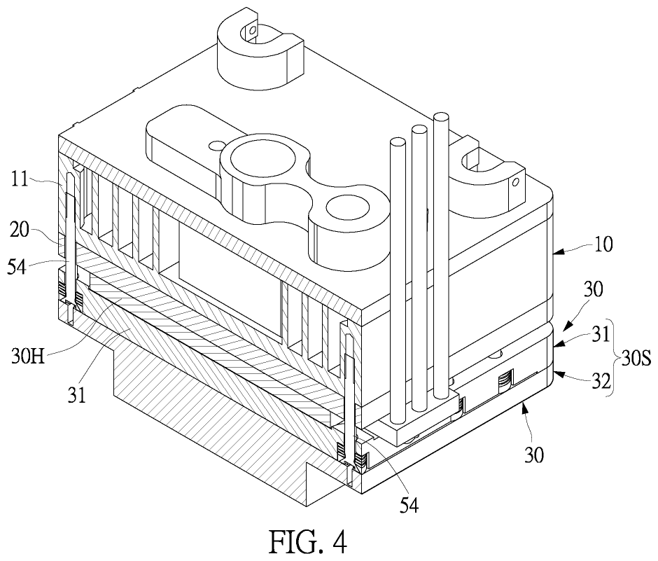

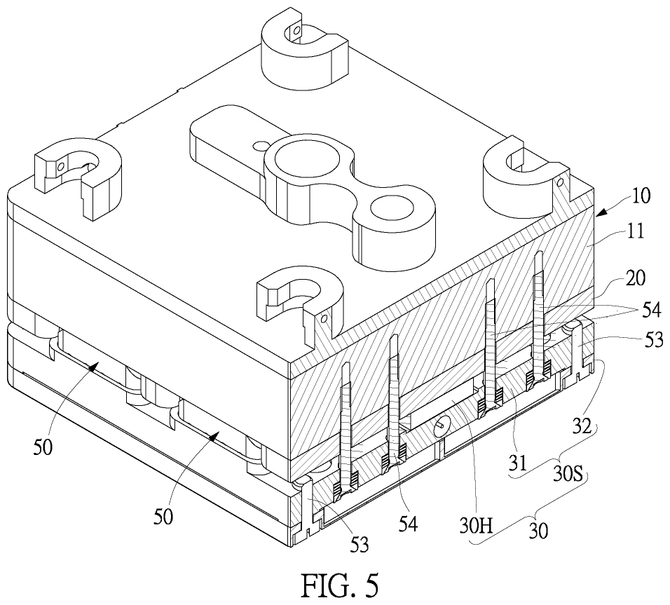

The high-temperature assembly 30 is disposed adjacent to (e.g., is disposed below) the low-temperature assembly 10. The high-temperature assembly 30 includes a high-temperature source 30H and a base 30S. The high-temperature source 30H is disposed on the base 30S. In addition, the high-temperature source 30H is configured to provide a predetermined high temperature, or can be referred to as a temperature rising assembly. The temperature rising assembly is, for example, a resistive heater or a cooling chip. A surface (e.g., a lower surface) of the base 30S is configured to directly contact the device under test T, and the low-temperature assembly 10 and/or the high-temperature source 30H conducts a predetermined temperature to the device under test T. Specifically, the base 30S includes a heater fixing base 31 and a device-under-test interface base 32. The heater fixing base 31 is configured to hold the high-temperature source 30H. In detail, the high-temperature source 30H can be fixed to a top portion of the heater fixing base 31 (as shown in FIG. 4), or can be held in the heater fixing base 31. As shown in FIG. 5, the device-under-test interface base 32 is connected to the heater fixing base 31. For example, the device-under-test interface base 32 is fixedly connected below the heater fixing base 31 via a screw 53, and the device-under-test interface base 32 is configured to directly contact the device under test T, and may also be referred to as a DUT adapter.

A main feature of the present disclosure is the gap adjusting member 50. One end of the gap adjusting member 50 is connected to the low-temperature assembly 10, and another end of the gap adjusting member 50 is disposed on the high-temperature assembly 30 (e.g., being disposed on the base 30S). The gap adjusting member 50 is configured to adjust a mechanical coupling condition between the low-temperature assembly 10 and the high-temperature assembly 30 in response to a temperature change of the high-temperature source 30H. When a temperature of the high-temperature source 30H rises (e.g., a heating operation state), the mechanical coupling condition corresponds to a lower thermal conductivity level. When the temperature of the high-temperature source 30H decreases (e.g., a cooling operation state), the mechanical coupling condition corresponds to a higher thermal conductivity level. Firstly, the higher or lower thermal conductivity level mentioned in the present disclosure refers to a relative comparison between thermal conductivity levels of the contact-type temperature control testing device 1 formed under different operating temperature states. Furthermore, the mechanical coupling condition mentioned in the present disclosure refers to a relative mechanical relationship between the low-temperature assembly 10 and the high-temperature assembly 30, and can cover situations in which surfaces of the low-temperature assembly 10 and the high-temperature assembly 30 contact each other or a space is present between the surfaces of the low-temperature assembly 10 and the high-temperature assembly 30. Specifically, in a configuration where the surfaces of the low-temperature assembly 10 and the high-temperature assembly 30 continuously contact each other, the mechanical coupling condition is characterized by strength of a thermal contact force (or a contact pressure) between the low-temperature assembly 10 and the high-temperature assembly 30. In a configuration where a space is present between the surfaces of the low-temperature assembly 10 and the high-temperature assembly 30, the mechanical coupling condition is characterized by a relative spaced distance between the low-temperature assembly 10 and the high-temperature assembly 30. Simply put, the mechanical coupling condition of the present disclosure can include the thermal contact force or the relative spaced distance.

In the present embodiment, the gap adjusting member 50 is made of a material that undergoes a thermally induced displacement in response to a temperature change, so as to change the mechanical coupling condition between the low-temperature assembly 10 and the high-temperature assembly 30. The thermally induced displacement refers to expansion or deformation generated in response to the temperature change. Specifically, the gap adjusting member 50 is made of a material having a thermal expansion coefficient that is greater than those of other components (e.g., the main body 11 or the base 30S). Such material can be, for example, a metal material or Teflon in an engineering plastic material.

When the temperature of the high-temperature source 30H rises (e.g., in the heating operation state), the gap adjusting member 50 is actuated in response to a high temperature (i.e., undergoes thermal expansion). The thermal contact force (or the contact pressure) between the low-temperature assembly 10 and the high-temperature assembly 30 is relatively decreased, or the relative spaced distance between the low-temperature assembly 10 and the high-temperature assembly 30 is relatively increased. In the above-mentioned two states, the degree of heat transfer between the low-temperature assembly 10 and the high-temperature assembly 30 is reduced, thereby reducing heat transfer from the high-temperature assembly 30 to the low-temperature assembly 10. In other words, in a process of increasing a test temperature with heating of the high-temperature source 30H, a decreased thermal contact force or an increased gap can both reduce an influence of the low-temperature assembly 10 on a test adapter base, so as to correspond to the lower thermal conductivity level. Conversely, when the temperature of the high-temperature source 30H decreases (e.g., in the cooling operation state), a reverse actuation (e.g., thermal contraction) is generated. The thermal contact force (or the contact pressure) between the low-temperature assembly 10 and the high-temperature assembly 30 is relatively increased, or the relative spaced distance between the low-temperature assembly 10 and the high-temperature assembly 30 is relatively decreased, so as to increase the degree of heat transfer and facilitate a low temperature to be conducted to the device under test T. In other words, in a process of decreasing the test temperature with temperature reduction of the high-temperature source 30H, an increased thermal contact force or a decreased gap can both enable the low-temperature assembly 10 to better contact the heater fixing base 31. This facilitates the low-temperature assembly 10 to decrease a temperature for testing the device-under-test interface base 32. In the following descriptions, a gap adjusting member will be exemplified, and specific details thereof will be provided.

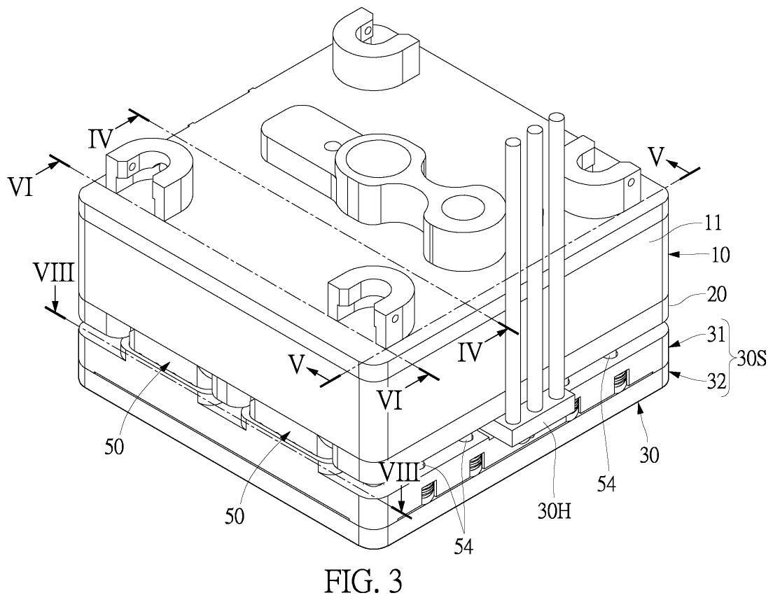

In the present embodiment, a thermal expansion change amount of the gap adjusting member 50 between a heating operation and a cooling operation is sufficient to change a relative distance between the low-temperature assembly 10 and the high-temperature assembly 30. Hence, the gap adjusting member 50 is also referred to as a thermal lifting member in the present disclosure. In other words, a height of the gap adjusting member 50 (the thermal lifting member) can be adjusted in compliance with the thermally induced displacement generated by the temperature change. As shown in FIG. 3 and FIG. 6 to FIG. 8, the gap adjusting member 50 of the present embodiment includes a lifting main body 501 and a plurality of thermal conductors 502. The lifting main body 501 can be a columnar structure that is made of a Teflon material having a high expansion coefficient. In the present embodiment, a bottom portion of the lifting main body 501 of the gap adjusting member 50 is accommodated in a recess of the heater fixing base 31. However, the present disclosure is not limited thereto. One end of the lifting main body 501 of the gap adjusting member 50 can downwardly pass through the heater fixing base 31, and extend to an upper surface of the device-under-test interface base 32. The above-mentioned configuration can increase an overall height of the gap adjusting member 50. In this way, the thermal expansion change amount can be increased. That is, a height change amount of the gap adjusting member 50 between the heating operation and the cooling operation can be increased.

Another end of the gap adjusting member 50 (i.e., a top surface of the lifting main body 501) is connected to a lower surface of the main body 11 of the low-temperature assembly 10, and is adjacent to an outer periphery of the main body 11. Such design can prevent the gap adjusting member 50 from affecting conduction of the low temperature to a center region of the device-under-test interface base 32 (i.e., a region that corresponds to the device under test T). Furthermore, since the bottom portion of the lifting main body 501 is accommodated in the heater fixing base 31, only the top surface contacts the low-temperature assembly 10. Accordingly, in the present embodiment, a contact area between the lifting main body 501 of the gap adjusting member 50 and the high-temperature assembly 30 is greater than a contact area between the lifting main body 501 and the low-temperature assembly 10. The above-mentioned structure can also increase a thermal expansion change amount of the lifting main body 501. Preferably, a top end of the lifting main body 501 has a tilt angle, so as to further reduce the contact area between the lifting main body 501 and the low-temperature assembly 10.

As mentioned above, the gap adjusting member 50 of the present embodiment further includes the thermal conductors 502, such as thermally conductive metal pins. The thermal conductors 502 pass through the lifting main body 501 of the gap adjusting member 50, and an end of the thermal conductor 502 contacts the high-temperature source 30H. In this way, the thermal conductors 502 can better conduct heat of the high-temperature source 30H to the lifting main body 501 of the gap adjusting member 50, so that the lifting main body 501 of the gap adjusting member 50 has an increased height due to the thermal expansion and a gap between the low-temperature assembly 10 and the high-temperature assembly 30 is increased.

In other embodiments, the gap adjusting member can also be a rod-like structure, such as an aluminum alloy screw. The aluminum alloy screws are disposed between the low-temperature assembly 10 and the high-temperature assembly 30. One end of the aluminum alloy screw is locked with the low-temperature assembly 10, and another end of the aluminum alloy screw is locked with the heater fixing base 31 of the base 30S. A length of the aluminum alloy screw can be adjusted in compliance with the thermally induced displacement generated by the temperature change, thereby adjusting the mechanical coupling condition (e.g., the thermal contact force) between the low-temperature assembly 10 and the high-temperature assembly 30.

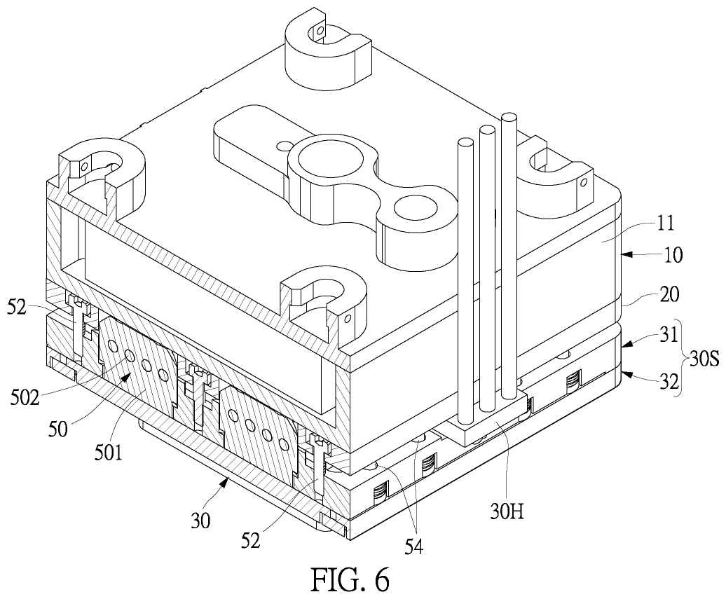

Preferably, the contact-type temperature control testing device 1 of the present embodiment further includes a low-temperature conductor 20. The low-temperature conductor 20 is fixed between the lower surface of the main body 11 of the low-temperature assembly 10 and the high-temperature assembly 30. As shown in FIG. 6, the low-temperature conductor 20 is downwardly connected to the heater fixing base 31 via a screw 52. The high-temperature source 30H abuts against a bottom surface of the low-temperature conductor 20. Regarding the degree of abutment mentioned here, a narrow gap or a space is actually present. As shown in FIG. 4 or FIG. 5, the heater fixing base 31 and the low-temperature conductor 20 are jointly fixed to the main body 11 of the low-temperature assembly 10 via a screw 54.

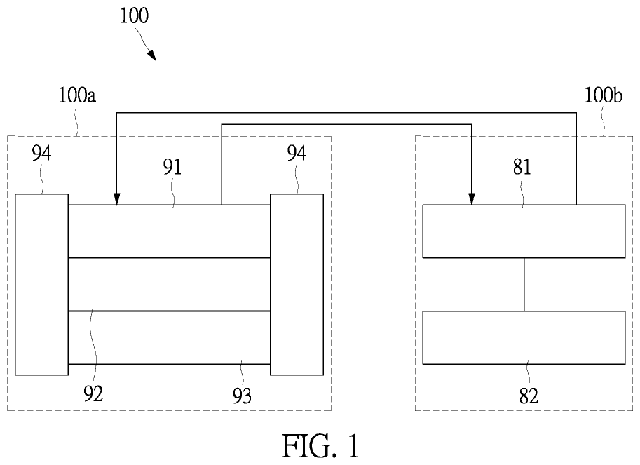

From a microscopic perspective, any surface that appears to be smooth is actually uneven. When two surfaces are in contact with each other, actual contact (solid-solid contact) takes place only at peaks of few asperities, and gaps that are filled with a medium (which is usually air) are present in most areas. Stationary air has a very low coefficient of thermal conductivity (about 0.026 W/m. K). Regarding the mechanism adopted in the present disclosure, thermal contact resistance of narrow gaps between two contact surfaces is formed due to low thermal conductivity of air, thereby weakening a thermal conductivity effect. In a high-temperature test situation, by decreasing the thermal contact force or increasing the relative spaced distance, heat transfer is blocked in the present embodiment. Accordingly, a large amount of heat sources of the high-temperature assembly 30 can be prevented from being transferred to the low-temperature assembly 10, so as to achieve effects of preventing a temperature of a casing (such as an outer housing 94 of FIG. 1) of the contact-type temperature control testing device 1 from being overly high or reducing a load of a chiller. In addition, a space formed by the relative spaced distance between the low-temperature assembly 10 and the high-temperature assembly 30 can be used as a thermal insulation structure. Conversely, in a low-temperature test situation, by increasing the thermal contact force or decreasing the relative spaced distance, heat transfer from the low-temperature assembly 10 to the device-under-test interface base 32 is increased in the present embodiment, so that the device-under-test interface base 32 can effectively reach a set temperature.

It should be noted that, by using a characteristic of a thermal conduction coefficient (otherwise referred to as a coefficient of thermal conductivity) of a material being affected by a temperature, the low-temperature conductor 20 is added in the present embodiment. In the present embodiment, a material of the low-temperature conductor 20 preferably has an improved thermal conduction coefficient at a lower temperature. For example, coefficients of thermal conductivity of aluminum nitride (AIN), silicon carbide (SiC), and other wide bandgap semiconductors decrease significantly as the temperature rises. In other words, such wide bandgap semiconductors have a large slope. For example, graphite also has similar characteristics. However, for the graphite, its purity, grain size, and crystallization degree will also affect an absolute value of the coefficient of thermal conductivity and a specific curve that changes with the temperature. Specifically, the low-temperature conductor 20 can be the aluminum nitride (AIN), the graphite, or a combination thereof. The graphite can be disposed on a surface of the aluminum nitride (AIN) that faces toward the low-temperature assembly 10 and/or the high-temperature assembly 30. Through the configuration in the present embodiment, under a low-temperature test condition, heat of the low-temperature assembly 10 can be easily conducted to the high-temperature assembly 30 and its device-under-test interface base 32 via the low-temperature conductor 20. Under a high-temperature test condition, heat of the high-temperature source 30H is less likely to be conducted to the low-temperature assembly 10 via the low-temperature conductor 20.

### Second Embodiment

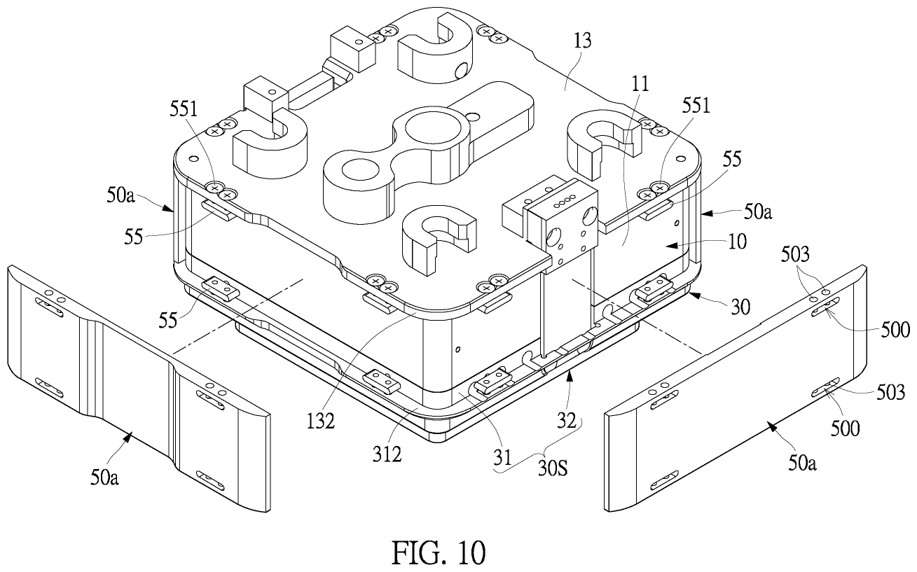

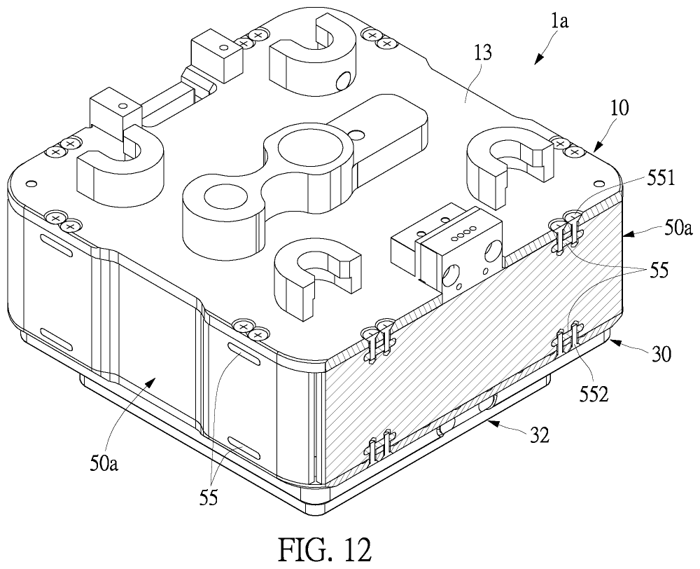

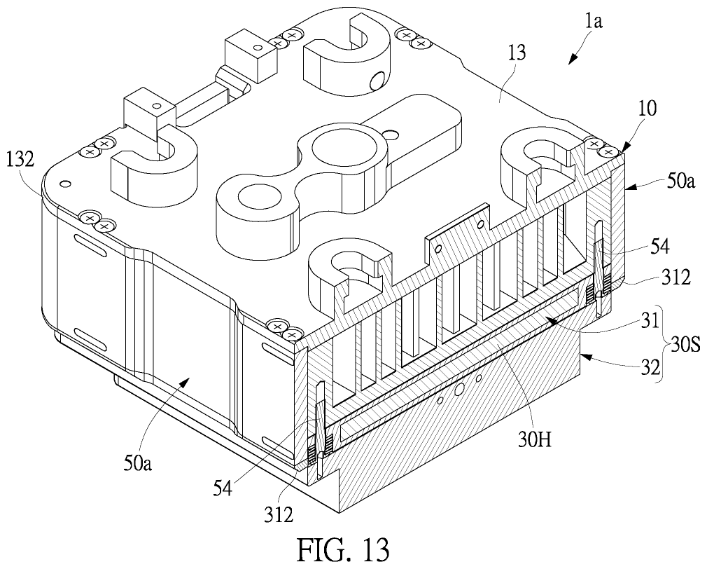

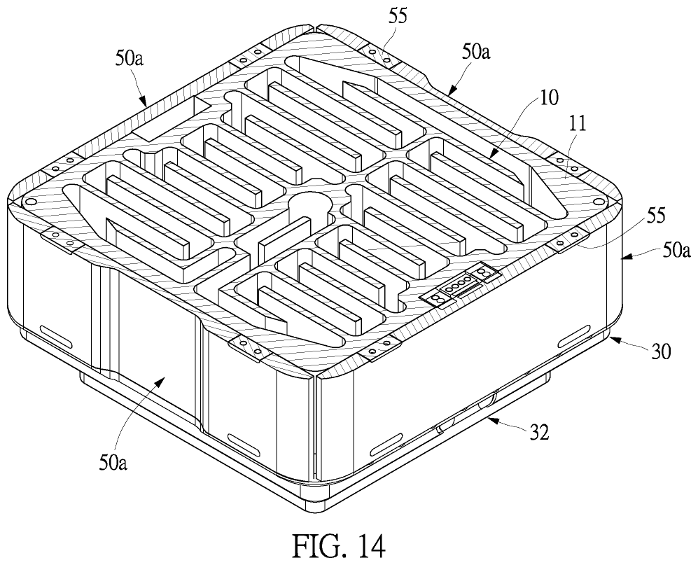

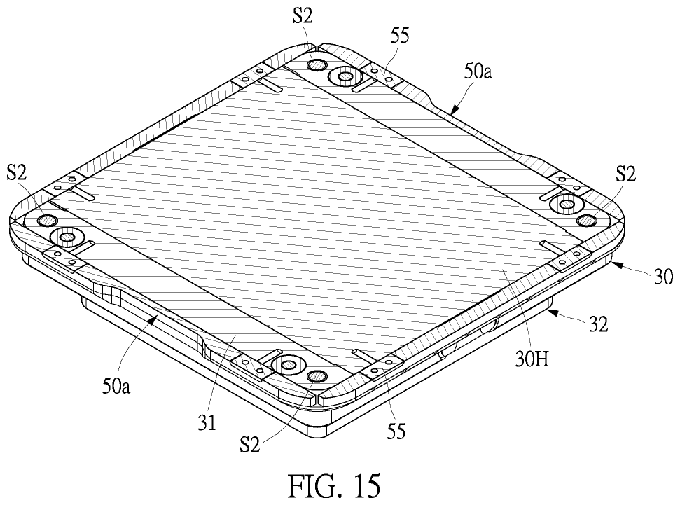

Reference is made to FIG. 10 to FIG. 15. Similar to the above-mentioned embodiment, a contact-type temperature control testing device la of the present embodiment includes a low-temperature assembly 10 that is configured to provide a predetermined low temperature, a high-temperature assembly 30 that is disposed adjacent to the low-temperature assembly 10, and a gap adjusting member 50a that is disposed between the low-temperature assembly 10 and the high-temperature assembly 30. The low-temperature assembly 10 has a main body 11, and the main body 11 has a top edge. The top edge can be an extension of a periphery of a detachable cover plate. The high-temperature assembly 30 similarly includes a high-temperature source 30H and a base 30S. The base 30S includes a heater fixing base 31 and a device-under-test interface base 32. As shown in FIG. 15, a screw S2 is used to upwardly pass through the device-under-test interface base 32 and be connected to the heater fixing base 31, so that the device-under-test interface base 32 is connected below the heater fixing base 31 and is configured to directly contact a device under test T. The high-temperature source 30H of the present embodiment is held in the heater fixing base 31. As shown in FIG. 13, the heater fixing base 31 is fixed to the low-temperature assembly 10 via a screw 54.

The main difference between the present embodiment and the above-mentioned embodiment is the shape and the configuration of a gap adjusting member. Regarding the gap adjusting member of the present embodiment, a plurality of gap adjusting members 50a that are plate-shaped are provided. A thermal expansion change amount of the gap adjusting member 50a between a heating operation and a cooling operation is also sufficient to change a relative distance between the low-temperature assembly 10 and the high-temperature assembly 30. Hence, the gap adjusting member 50a can also be referred to as a thermal lifting member. With an increase in volume, the gap adjusting member (thermal lifting member) 50a has a plate body, and is disposed between the low-temperature assembly 10 and the high-temperature assembly 30, so as to maintain a contact force or a relative spaced distance between the low-temperature assembly 10 and the high-temperature assembly 30 when being downwardly pressed for testing purposes. The gap adjusting member 50a can have a greater height to increase the thermal expansion change amount. One end of the gap adjusting member 50a is connected to a bottom edge of the heater fixing base 31, and another end of the gap adjusting member 50a upwardly extends and is connected to the top edge of the main body 11 of the low-temperature assembly 10. A bottom end of the plate-shaped gap adjusting member 50a can be directly fastened to the bottom edge of the heater fixing base 31 via a screw, and a top end of the gap adjusting member 50a can be directly fastened to the top edge of the main body 11 via a screw.

Specifically, the gap adjusting member 50a of the present embodiment can also be made of an engineering plastic material, such as Teflon. The gap adjusting member 50a is disposed on an outer side of the main body 11 of the low-temperature assembly 10 and the heater fixing base 31, and can, for example, act as an outer side wall of the main body 11 of the low-temperature assembly 10 and the heater fixing base 31. By being disposed on the outer side, the gap adjusting member 50a can be further prevented from affecting conduction of a low temperature to a center region of the device-under-test interface base 32 (i.e., a region that corresponds to the device under test T). Moreover, by acting as the outer side wall of the main body 11 and the heater fixing base 31, the gap adjusting member 50a can slightly block temperature conduction of heat from the low-temperature assembly 10 and the heater fixing base 31 toward a casing (such as an outer housing 94 of FIG. 1) of the contact-type temperature control testing device la, so as to achieve an improved effect of preventing overheating of the casing.

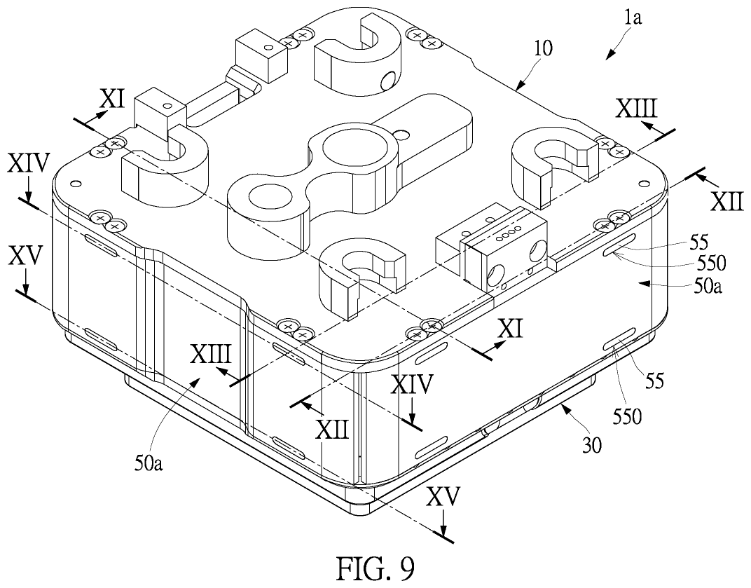

In the present disclosure, low structural strength of the engineering plastic material and a low mechanical performance parameter are further taken into consideration, and bearing a screw fastening structure with a high load is prevented. Preferably, four assembly through holes 500 that are horizontally oriented are formed in each of the gap adjusting members (thermal lifting members) 50a in the present embodiment. Two of the assembly through holes 500 are adjacent to a top edge of the gap adjusting member 50a, and another two of the assembly through holes 500 are adjacent to a bottom edge of the gap adjusting member 50a. Furthermore, each of the assembly through holes 500 is in spatial communication with a top end surface and a bottom end surface of the gap adjusting member 50a via two screw through holes 503. As shown in FIG. 9, a threaded member 55 is embedded in each of the assembly through holes 500. The threaded member 55 is a flat metal block, and has two screw holes.

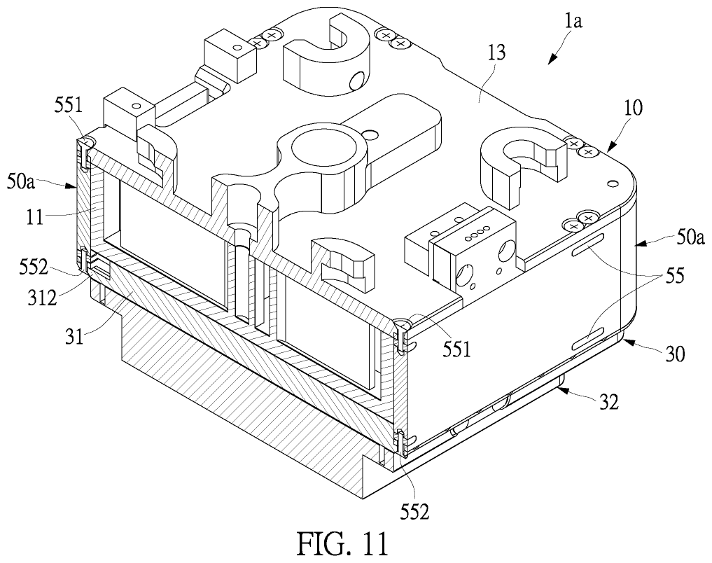

As shown in FIG. 10, the top edge of the main body 11 of the low-temperature assembly 11 outwardly extends to form a first connecting portion 132. The bottom edge of the heater fixing base 31 outwardly extends to form a second connecting portion 312. Specifically, the first connecting portion 132 is formed by outward extension of a top cover 13 of the main body 11. The gap adjusting member 50a is disposed between the first connecting portion 132 and the second connecting portion 312. The first connecting portion 132 is threadedly engaged with the threaded member 55 by using a screw 551 (as shown in FIG. 11) to pass through the screw through hole 503 of the gap adjusting member (thermal lifting member) 50a. The second connecting portion 312 is also threadedly engaged with the threaded member 55 by using a screw (as shown in FIG. 11) to pass through the screw through hole 503 of the gap adjusting member (thermal lifting member) 50a.

The present disclosure further provides a method of controlling a temperature of the device under test T in a direct contact manner. The method includes the following steps: providing the above-mentioned contact-type temperature control testing device (1 or la); using a surface (e.g., a lower surface) of the base 30S of the high-temperature assembly 30 to directly contact the device under test T; providing, by the high-temperature source 30H, a predetermined high temperature in a heating operating state, and using the gap adjusting member (50, 50a) to adjust a mechanical coupling condition between the low-temperature assembly 10 and the high-temperature assembly 30 in response to a temperature change of the high-temperature source 30H, so as to correspond to a lower thermal conductivity level; and providing, by the low-temperature assembly 10, the predetermined low temperature in a cooling operation state, and using the gap adjusting member (50, 50a) to adjust the mechanical coupling condition between the low-temperature assembly 10 and the high-temperature assembly 30 in response to the temperature change of the high-temperature source 30H, so as to correspond to a higher thermal conductivity level.

The present disclosure further provides a temperature controlling system, which includes: the above-mentioned contact-type temperature control testing device (1 or la); a cooling module 81 connected to the low-temperature assembly 10; and a temperature controlling module 82. The temperature controlling module 82 is configured to monitor and adjust a temperature of the low-temperature assembly 10 and a temperature of the high-temperature assembly 30, so as to maintain an estimated temperature of the surface of the base 30S that contacts the device under test T.

The present disclosure further provides a tested device, which is the electronic device under test T having a temperature that is controlled by the above-mentioned method.

### Beneficial Effects of the Embodiments

In conclusion, in the contact-type temperature control testing device provided by the present disclosure, the gap adjusting member can adjust the mechanical coupling condition between the low-temperature assembly and the high-temperature assembly in response to the temperature change of the high-temperature source. During a high-temperature operation, the mechanical coupling condition corresponds to the lower thermal conductivity level, and conduction of heat from the high-temperature assembly to the low-temperature assembly is reduced as much as possible, so as to prevent a slow temperature rise in a device-under-test (DUT) adapter, prevent the casing of the contact-type temperature control testing device from having an overly high temperature, and avoid situations that may result in an increased load or abnormal shutdown of a chiller of a temperature control testing system. During a low-temperature operation, the mechanical coupling condition corresponds to the higher thermal conductivity level, so that thermal conduction of the low-temperature assembly can effectively reach the DUT adapter. In this way, a low temperature that is set can be quickly achieved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A contact-type temperature control testing device, directly contacting a device under test and performing temperature control, the contact-type temperature control testing device comprising:
a low-temperature assembly, wherein the low-temperature assembly is configured to provide a predetermined low temperature;
a high-temperature assembly, wherein the high-temperature assembly is disposed adjacent to the low-temperature assembly, and includes a high-temperature source and a base; and wherein the high-temperature source is disposed on the base and is configured to provide a predetermined high temperature, a surface of the base is configured to directly contact the device under test, and at least one of the low-temperature assembly or the high-temperature source conducts a predetermined temperature to the device under test; and
a gap adjusting member, wherein one end of the gap adjusting member is connected to the low-temperature assembly, and another end of the gap adjusting member is disposed on the high-temperature assembly;
wherein the gap adjusting member is configured to adjust a mechanical coupling condition between the low-temperature assembly and the high-temperature assembly in response to a temperature change of the high-temperature source; and wherein the mechanical coupling condition corresponds to a lower thermal conductivity level when a temperature of the high-temperature source rises, and the mechanical coupling condition corresponds to a higher thermal conductivity level when the temperature of the high-temperature source decreases.

2. The contact-type temperature control testing device according to claim 1, wherein the mechanical coupling condition includes a thermal contact force or a relative spaced distance; wherein, when the temperature of the high-temperature source rises, the thermal contact force between the low-temperature assembly and the high-temperature assembly is relatively decreased, or the relative spaced distance between the low-temperature assembly and the high-temperature assembly is relatively increased, so as to correspond to the lower thermal conductivity level; and wherein, when the temperature of the high-temperature source decreases, the thermal contact force between the low-temperature assembly and the high-temperature assembly is relatively increased, or the relative spaced distance between the low-temperature assembly and the high-temperature assembly is relatively decreased, so as to correspond to the higher thermal conductivity level.

3. The contact-type temperature control testing device according to claim 1, wherein the gap adjusting member is made of a material configured to undergo a thermally induced displacement in response to a temperature change, so as to change the mechanical coupling condition between the low-temperature assembly and the high-temperature assembly.

4. The contact-type temperature control testing device according to claim 3, wherein the base includes a heater fixing base and a device-under-test interface base, the high-temperature source is fixed to the heater fixing base, the another end of the gap adjusting member is disposed on the base, and the device-under-test interface base is connected to the heater fixing base and is configured to directly contact the device under test.

5. The contact-type temperature control testing device according to claim 4, wherein the gap adjusting member is an aluminum alloy screw, one end of the aluminum alloy screw is locked with the low-temperature assembly, another end of the aluminum alloy screw is locked with the heater fixing base, and a length of the aluminum alloy screw is adjusted in compliance with the thermally induced displacement generated by the temperature change.

6. The contact-type temperature control testing device according to claim 4, wherein the gap adjusting member is a thermal lifting member, a height of the thermal lifting member is adjusted in compliance with the thermally induced displacement generated by the temperature change, and the thermal lifting member is made of a Teflon material.

7. The contact-type temperature control testing device according to claim 6, wherein an end of the thermal lifting member downwardly passes through the heater fixing base, and extends to an upper surface of the device-under-test interface base.

8. The contact-type temperature control testing device according to claim 6, wherein a contact area between the thermal lifting member and the high-temperature assembly is greater than a contact area between the thermal lifting member and the low-temperature assembly.

9. The contact-type temperature control testing device according to claim 6, wherein the thermal lifting member includes a thermal conductor, and an end of the thermal conductor contacts the high-temperature source.

10. The contact-type temperature control testing device according to claim 6, wherein the low-temperature assembly has a main body; and wherein another end of the thermal lifting member is connected to a lower surface of the main body, and is adjacent to an outer periphery of the main body.

11. The contact-type temperature control testing device according to claim 6, wherein an end of the thermal lifting member is connected to a bottom edge of the heater fixing base, the low-temperature assembly has a main body, and another end of the thermal lifting member upwardly extends and is connected to a top edge of the main body.

12. The contact-type temperature control testing device according to claim 11, wherein the top edge of the main body of the low-temperature assembly outwardly extends to form a first connecting portion, the bottom edge of the heater fixing base outwardly extends to form a second connecting portion, and the thermal lifting member is disposed between the first connecting portion and the second connecting portion.

13. The contact-type temperature control testing device according to claim 6, wherein the thermal lifting member is disposed on an outer side of the low-temperature assembly and the heater fixing base.

14. The contact-type temperature control testing device according to claim 1, further comprising a low-temperature conductor, wherein the low-temperature conductor is disposed between a lower surface of the low-temperature assembly and the high-temperature assembly.

15. The contact-type temperature control testing device according to claim 14, wherein the low-temperature conductor is aluminum nitride, graphite, or a combination thereof.

16. A method of controlling a temperature of a device under test in a direct contact manner, comprising:
providing the contact-type temperature control testing device as claimed in claim 1;
using the surface of the base of the high-temperature assembly to directly contact the device under test;
providing, by the high-temperature source, the predetermined high temperature in a heating operation state, and using the gap adjusting member to adjust the mechanical coupling condition between the low-temperature assembly and the high-temperature assembly in response to the temperature change of the high-temperature source, so as to correspond to the lower thermal conductivity level; and
providing, by the low-temperature assembly, the predetermined low temperature in a cooling operation state, and using the gap adjusting member to adjust the mechanical coupling condition between the low-temperature assembly and the high-temperature assembly in response to the temperature change of the high-temperature source, so as to correspond to the higher thermal conductivity level.

17. A temperature controlling system, comprising:
the contact-type temperature control testing device as claimed in claim 1;
a cooling module connected to the low-temperature assembly; and
a temperature controlling module, wherein the temperature controlling module is configured to monitor and adjust a temperature of the low-temperature assembly and a temperature of the high-temperature assembly, so as to maintain an estimated temperature of the surface of the base that contacts the device under test.

18. A tested device, characterized in that the tested device is an electronic device under test having a temperature that is controlled by the method as claimed in claim 16.
